(19) United States
(12) Patent Application Publication
(10) Pub. No.: US 2010/0051082 A1
(43) Pub. Date: Mar. 4, 2010

(54) THIN FILM SOLAR CELL MODULE AND METHOD OF MANUFACTURING THE SAME

(75) Inventors: Yeon-Il KANG, Yongin-si (KR); Jin-Seock KIM, Cheonan-si (KR); Czang-Ho LEE, Hwasung-si (KR); Hee-Chan LEE, Cheonan-si (KR); Ku-Hyun KANG, Suwon-si (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 12/421,158

(22) Filed: Apr. 9, 2009

(30) Foreign Application Priority Data
Aug. 29, 2008 (KR) 10-2008-0085247

(51) Int. Cl. H01L 31/048; H01L 31/18

(52) U.S. Cl. 136/244; 438/66

(57) ABSTRACT

A thin film solar cell module includes a front substrate; a plurality of thin film solar cells disposed on the front substrate; a rear substrate disposed on the thin film solar cells; a plurality of inter-connection terminals electrically connected to the thin film solar cells, respectively, and exposed to an exterior surface of at least one of the front and rear substrates; and a connector electrically connecting the inter-connection terminals in a series or parallel configuration.

This application claims priority to Korean Patent Application No. 10-2008-0085247, filed on Aug. 29, 2008, and all the benefits accruing therefrom under 35 U.S.C. §119, the contents of which in its entirety are herein incorporated by reference.

### BACKGROUND OF THE INVENTION

(a) Field of the Invention

This disclosure relates to a thin film solar cell module and method of manufacturing the same.

(b) Description of the Related Art

A solar cell converts solar energy into electrical energy. The solar cell is a diode consisting of a PN junction, and may be classified according to a material used in a light absorption layer.

A solar cell including silicon in the light absorption layer may be classified as a crystalline (monocrystalline or polycrystalline) solar cell, a substrate solar cell, or a thin film (crystalline or amorphous) solar cell.

The thin film solar cell can be formed by disposing a film onto a substrate, which includes a thin layer of glass or plastic. In a commercially available thin film solar cell, a diffusion distance of a carrier can be very short due to a thickness characteristic of the thin film solar cell compared to that of a crystalline silicon solar cell. Also, if the thin film solar cell includes only a PN junction structure, a collection efficiency of electron-hole pairs generated by sunlight can be less than a collection efficiency of a crystalline silicon solar cell. Therefore, the thin film solar cell can include a PIN structure wherein an intrinsic semiconductor-based light-absorbing layer having a high light absorption can be interposed between a P-type semiconductor and an N-type semiconductor.

An amount of electricity from one solar cell can be very small, and a voltage thereof can be low. Therefore, to increase electricity generation, a plurality of solar cells can be electrically connected to each other to form a unit, which is referred to as a solar cell module.

A plurality of thin film solar cells can each have similar performance within a solar cell module, thus modules of thin film solar cells can include a plurality of thin film solar cells. In contrast, in a commercial module using a crystalline solar cell, a single crystalline solar cell is used. Also, a unit cell in a solar cell produced by a pilot line, or using first or second generation liquid crystal display (“LCD”) production equipment, can have a small size, and a solar cell module product thereof can have a different size from a production product. Accordingly, an amount of work per unit area can be increased if a solar cell having a small size is fabricated, and installation of a pilot or production line can be difficult. Also a size of a frame for forming modules of the solar cells may need to be increased, thereby increasing a load per unit area. Also, in a solar cell module including a plurality of solar cells, a connection line between each solar cell is disposed inside a module such that the whole module may be faulty or inoperable when the connecting line deteriorates from use or fails, such as from use over a long period of time.

### BRIEF SUMMARY OF THE INVENTION

Accordingly, an embodiment, thin film solar cells are electrically connected to each other at an exterior surface thereof to improve productivity.

The above described and other drawbacks are alleviated by a thin film solar cell module including: a front substrate; a plurality of thin film solar cells disposed on the front substrate; a rear substrate disposed on the thin film solar cells; a plurality of inter-connection terminals electrically connected to the thin film solar cells, respectively, and disposed on the rear substrates; and a connector electrically connecting the inter-connection terminals in a series or parallel configuration.

In an embodiment, the thin film solar cell module may further include an outer connection terminal electrically connected to at least one of the inter-connection terminals and disposed on the rear substrate, wherein the outer connection terminal is electrically connected to at least one other thin film solar cell module.

In an embodiment, the thin film solar cell module may further include a bypass diode disposed inside the outer connection terminal.

In an embodiment, the inter-connection terminals and the thin film solar cells may be electrically connected to each other through busbars which penetrate the rear substrate.

In an embodiment, the thin film solar cell module may further include a front plastic layer interposed between the front substrate and the thin film solar cells.

In an embodiment, the front plastic layer may be made of a polyethylene vinyl acetate sheet.

In an embodiment, the thin film solar cell module may further include a rear plastic layer interposed between the rear substrate and the thin film solar cells.

In an embodiment, the rear plastic layer may be made of a polyethylene vinyl acetate sheet.

In an embodiment, the rear substrate includes glass, a back sheet, or a combination including glass and a back sheet.

In an embodiment, the front substrate includes a low-iron enhanced glass.

In an embodiment, the back sheet may include polyethylene terephthalate (“PET”).

Also disclosed is a method for manufacturing a thin film solar cell module, the method includes: disposing a plurality of thin film solar cells on a front substrate; disposing a rear plastic layer on a surface of the thin film solar cells; disposing a rear substrate on the rear plastic layer; laminating the rear plastic layer and the rear substrate; electrically connecting a plurality of inter-connection terminals disposed on the rear substrate to each of the thin film solar cells, respectively; and electrically connecting the inter-connection terminals to each other through a connector.

In an embodiment, the electrically connecting of the inter-connection terminals to the thin film solar cells further includes disposing busbars on the thin film solar cells, which penetrate the rear plastic layer and the rear substrate.

In an embodiment, the thin film solar cells are electrically connected to at least one other thin film solar cell module by an outer connection terminal, which includes a bypass diode.

In an embodiment, the method may further include, disposing a front plastic layer on the front substrate before arranging the thin film solar cells on the front substrate.

In an embodiment, the rear plastic layer is a polyethylene vinyl acetate sheet.

In an embodiment, the disposing of the rear plastic layer further includes disposing a polyethylene vinyl acetate sheet on an entire surface of the thin film solar cells.

In an embodiment, the thin film solar cell module may be manufactured to have a size which is the same size as a production product, and even if a short is generated a thin film solar cell, because a terminal is connected outside the rear substrate, the entire module may be repaired. Also, the output voltage and/or current may be controlled by selection of the connectivity of the terminals such that an amount of cable may be reduced, thereby improving economic efficiency.

In an embodiment, the inter-connection terminals and connector are configured to bypass one or more thin film solar cells.

In an embodiment, one or more of the thin film solar cells comprises a fault, and the fault is bypassed.

These and other features, aspects, and advantages of the disclosed embodiments will become better understood with reference to the following description and appended claims.

### BRIEF DESCRIPTION OF THE DRAWINGS

The disclosed subject matter is particularly pointed out and distinctly claimed in the claims at the conclusion of the specification. The above and other aspects, advantages, and features of the invention will become more apparent by describing in further detail exemplary embodiments thereof with reference to the attached drawings, in which:

FIG. 1 and FIG. 2 are a perspective views showing an exemplary embodiment of a manufacturing method of a thin film solar cell module;

FIG. 3 is a plan view showing an exemplary embodiment of a manufacturing method of a thin film solar cell module;

FIG. 4 is a cross-sectional view of an exemplary embodiment taken along line IV-IV′ line of FIG. 3; and

FIGS. 5 and 6 are equivalent circuit diagrams showing an exemplary embodiment of a method for electrically connecting thin film solar cells in a thin film solar cell module.

The detailed description explains the exemplary embodiments, together with aspects, advantages and features, by way of example with reference to the drawings.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. Aspects, advantages, and features of the present invention and methods of accomplishing the same may be understood more readily by reference to the following detailed description of preferred embodiments and the accompanying drawings. The present invention may, however, may be embodied in many different forms, and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Thus it will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of the present invention.

Spatially relative terms, such as “below”, “lower”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “lower” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings. However, the aspects, features, and advantages of the present invention are not restricted to the ones set forth herein. The above and other aspects, features, and advantages of the present invention will become more apparent to one of ordinary skill in the art to which the present invention pertains by referencing a detailed description of the present invention given below.

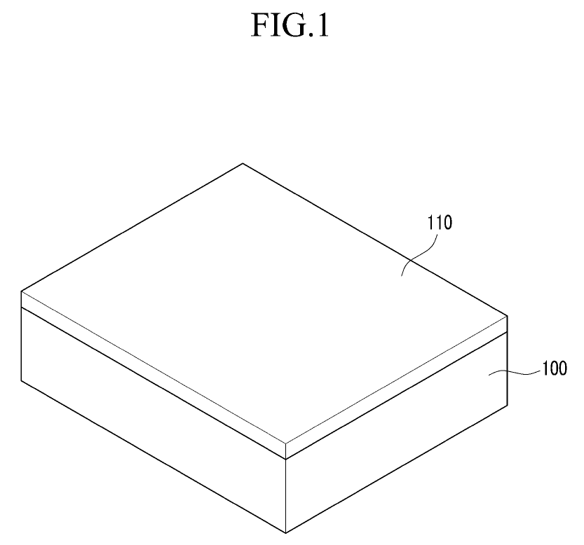

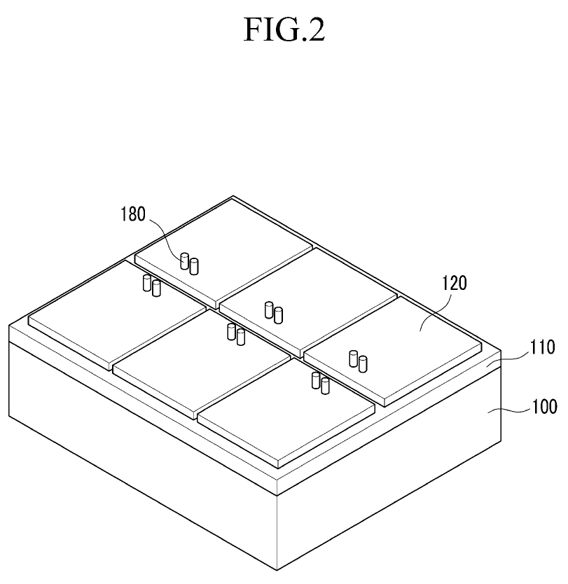

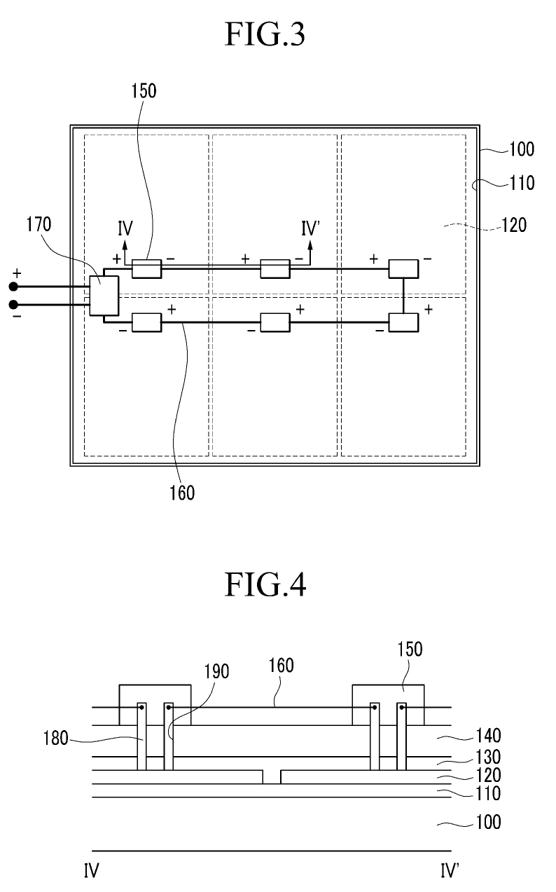

FIG. 1 and FIG. 2 are a perspective views showing an exemplary embodiment of a manufacturing method of a thin film solar cell module, and FIG. 3 is a plan view showing an exemplary embodiment of a manufacturing method of a thin film solar cell module according to an exemplary embodiment. FIG. 4 is a cross-sectional view taken along line IV-IV′ of FIG. 3.

Referring to FIG. 1, to manufacture a thin film solar cell module according to an exemplary embodiment, a glass substrate 100 is first disposed. The glass substrate 100 may comprise a low-iron enhanced glass, or the like, and can have an excellent transmittance to improve electrical energy conversion. In an embodiment, the glass substrate 100 may be treated to increase a light transmittance and to reduce a loss of surface light by reflection.

A front plastic (“EVA”) layer 110 is disposed on the glass substrate 100. In an embodiment, the front EVA layer is a sheet comprising polyethylene vinyl acetate, or the like. The front EVA layer 110 can comprise a vinyl film and can have a good transmittance, be shock absorbing, elastic, and have a high tensile strength. The front EVA layer 110 can be a copolymer of ethylene and vinyl acetate.

Referring to FIG. 2, a plurality of thin film solar cells 120 are disposed on the front EVA layer 110. A plurality of busbars 180, which are electrically connected to positive terminals (+) and negative terminals (−) of the thin film solar cell, respectively, are disposed on the thin film solar cells 120.

Referring to FIG. 3 and FIG. 4, a rear EVA layer 130 can be disposed on a rear surface of the thin film solar cells 120. The rear EVA layer 130 can comprise polyethylene vinyl acetate, or the like. In an embodiment, the rear EVA layer is a sheet. The front and rear EVA layers 110 and 130, respectively disposed on the front and rear surfaces of the thin film solar cells 120, can reduce or substantially prevent the deterioration of the thin film solar cells 120 and can attach the front substrate 100 and the rear substrate 140 to each other and seal them.

When the front and rear EVA layers 110 and 130 are exposed to ultraviolet rays for a long period of time, a color of at least one of the front and the rear EVA layers may change, and a moisture-proofing quality thereof may be deteriorated. In addition, when forming a solar cell module, it can be important to apply a process consistent with a characteristic of the EVA sheet to increase the lifetime of the module and to improve reliability.

The rear substrate 140 is disposed on the rear EVA sheet 130. The rear substrate 140 may comprise glass, a back sheet, or the like, or a combination comprising at least one of the foregoing materials. The glass can be thick and heavy, but can be inexpensive. The back sheet can be thin and light, but can be expensive. The back sheet may comprise polyethylene terephthalate (“PET”), or the like.

The rear EVA layer 130 and the rear substrate 140 can be compressed together at a high temperature in a vacuum state, thereby being solidly laminated together. The rear substrate 140 can be watertight, insulating, and can shield the thin film solar cells against ultraviolet rays. The rear EVA layer 130 and the rear substrate 140 can have a plurality of holes 190 through which the busbars 180 disposed on the thin film solar cells 120 penetrate. The thin film solar cells 120 may be electrically connected to another thin film solar cell disposed on the front substrate 100 through the holes 190.

A plurality of inter-connection terminals 150 are disposed on the rear substrate 140. The inter-connection terminals 150 can be disposed on an exterior surface of the thin film solar cell module, thus can be exposed to an exterior of the thin film solar cell module. The inter-connection terminals 150 may be electrically connected to a plurality of thin film solar cells 120 through the busbars 180. The inter-connection terminals 150 are disposed on the rear substrate 140, and can be exposed to an exterior surface of at least one of the front and rear substrates. The inter-connection terminals 150 may be electrically connected in a series or in a parallel configuration by a connector 160. In an embodiment, the inter-connection terminals 150 may be electrically connected in a series or in a parallel configuration by a plurality of connectors. The connector can be exposed to an exterior surface of at least one of the front and rear substrates, thus can be exposed to an exterior of the thin film solar cell module. As a result, the thin film solar cells 120 are electrically connected to each other through the busbars 180 on the rear substrate 140. FIG. 3 is an illustration of a manufacturing method of a thin film solar cell, and shows the inter-connection terminals 150 electrically connected in series by the connector 160.

Accordingly, if a fault, such as a short circuit, is generated in one or more of the thin film solar cells 120, the solar cell module may be repaired. Also, the inter-connection terminals 150 are electrically connected to the connector 160 outside the rear substrate 140 such that the output voltage and/or current may be controlled by changing the connectivity of the thin film solar cells. Thus, a connectivity between the connector 160 and the inter-connection terminals 150 can be changed after the manufacture of the module is completed. Accordingly, electrical connection of the thin film solar cells using a smaller number or a greater number of connectors, which can be a cable, than a number of connectors used in another thin film solar cell module is possible.

An outer connection terminal 170 is disposed on the rear substrate 140. The outer connection terminal 170 is electrically connected to at least one of the inter-connection terminals 150. A bypass diode can be used to allow the inter-connection terminals 150 to electrically connect the solar cells 120 to each other. In an embodiment, the bypass diode is only installed in the outer connection terminal 170. The outer connection terminal 170 can be electrically connected to another thin film solar cell module.

The thin film solar cell module according to an exemplary embodiment may be enclosed by a frame (not shown).

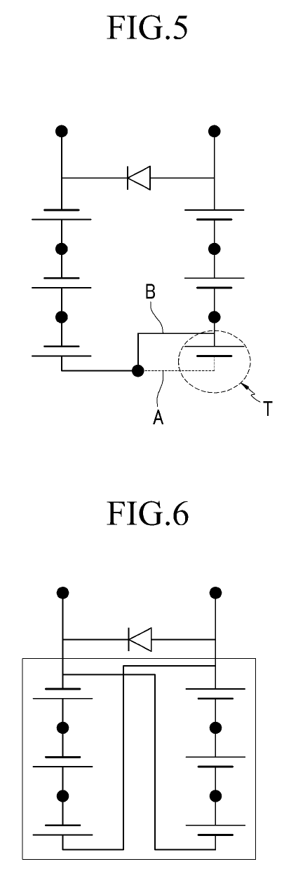

FIG. 5 to FIG. 6 are equivalent circuit diagrams showing another exemplary embodiment of a method for electrically connecting thin film solar cells in the thin film solar cell module.

Referring to FIG. 5, a plurality of inter-connection terminals 150 of FIG. 3 can be electrically connected in series. If one or more of the thin film solar cells 120 comprise a fault, such as a short circuit, the inter-connection terminal T at which the fault is generated can be bypassed and the thin film solar cell module may thus be repaired. In other words, a connector A, which was initially electrically connected to the inter-connection terminal T is removed and a new connector B is electrically connected to bypass the inter-connection terminal T at which the fault is generated.

Referring to FIG. 6, a plurality of inter-connection terminals 150 may be electrically connected in parallel by changing a connectivity of the thin film solar cells. Accordingly, an output voltage and/or current may be controlled through selection of the connectivity of the thin film solar cells.

A thin film solar cell module according to another exemplary embodiment is described with reference to FIG. 3 and FIG. 4.

In a thin film solar cell module according to an exemplary embodiment, an EVA layer 110 is disposed on a front substrate 100, and a plurality of thin film solar cells 120 are disposed on the EVA layer 110. A plurality of busbars 180, which are electrically connected to positive (+) and negative (−) terminals of the thin film solar cells, respectively, protrude from each of the thin film solar cells 120. The rear EVA layer 130, which has a plurality of holes 190 which are penetrated by the busbars 180, covers a front surface of the thin film solar cells 120. A rear substrate 140 having the holes 190 is penetrated by the busbars 180, which are disposed on the rear EVA layer 130. The busbars 180, which penetrate the holes 190 of the rear EVA layer 130 and the rear substrate 140, can be exposed and are electrically connected to a plurality of inter-connection terminals 150 disposed on the rear substrate 140, respectively. The inter-connection terminals 150 can be electrically connected to each other through the connector 160.

A thin film solar cell according to an exemplary embodiment includes an outer connection terminal 170 disposed on the rear substrate 140 electrically connected to the inter-connection terminals 150. The outer connection terminal 170 includes a bypass diode and is electrically connected to another thin film solar cell module.

The front and rear EVA layers 110 and 130, respectively, can comprise a vinyl film, which can have an excellent transmittance, be shock absorbing, elastic, and have high tensile strength. In an embodiment, the front and rear EVA layers can comprise a copolymer of ethylene and a vinyl acetate, or the like.

The glass substrate 100 may comprise a low-iron enhanced glass, or the like, and can have an excellent transmittance to improve electrical energy conversion. In an embodiment, the glass substrate 100 may be treated to increase a light transmittance and to reduce a loss of surface light by reflection.

The rear substrate 140 may comprise glass, a back sheet, or the like, or a combination comprising at least one of the foregoing materials. The back sheet may comprise polyethylene terephthalate, for example.

In a thin film solar cell module according to an exemplary embodiment, a plurality of thin film solar cells are disposed on a substrate to form a thin film solar cell module such that the thin film solar cell module has a size which is the same size as a size of a production product. In addition the thin film solar cell module may be produced using first or second generation liquid crystal display (“LCD”) production equipment.

While this invention has been described in connection with an exemplary embodiment, it is to be understood that the invention is not limited to the disclosed embodiments, but, on the contrary, is intended to cover various modifications and equivalent arrangements included within the spirit and scope of the appended claims.

What is claimed is:

1. A thin film solar cell module, comprising:
a front substrate;
a plurality of thin film solar cells disposed on the front substrate;
a rear substrate disposed on the thin film solar cells;
a plurality of inter-connection terminals electrically connected to the thin film solar cells, respectively, and disposed on the rear substrates; and
a connector electrically connecting the inter-connection terminals in a series or a parallel configuration.

2. The thin film solar cell module of claim 1, further comprising
an outer connection terminal electrically connected to at least one of the inter-connection terminals and disposed on the rear substrate, wherein the outer connection terminal is electrically connected to at least one other thin film solar cell module.

3. The thin film solar cell module of claim 2, further comprising
a bypass diode disposed inside the outer connection terminal.

4. The thin film solar cell module of claim 1, wherein
the inter-connection terminals and the thin film solar cells are electrically connected to each other through busbars which penetrate the rear substrate.

5. The thin film solar cell module of claim 1, further comprising
a front plastic layer interposed between the front substrate and the thin film solar cells.

6. The thin film solar cell module of claim 5, wherein the front plastic layer is made of a polyethylene vinyl acetate sheet.

7. The thin film solar cell module of claim 1, further comprising
a rear plastic layer interposed between the rear substrate and the thin film solar cells.

8. The thin film solar cell module of claim 7, wherein the rear plastic layer is made of a polyethylene vinyl acetate sheet.

9. The thin film solar cell module of claim 8, wherein
the rear substrate comprises glass, a back sheet, or a combination comprising glass and a back sheet.

10. The thin film solar cell module of claim 9, wherein
the back sheet comprises polyethylene terephthalate.

11. The thin film solar cell module of claim 1, wherein
the front substrate comprises a low-iron enhanced glass.

12. A method for manufacturing a thin film solar cell module, the method comprising:
disposing a plurality of thin film solar cells on a front substrate;
disposing a rear plastic layer on a surface of the thin film solar cells;
disposing a rear substrate on the rear plastic layer;
laminating the rear plastic layer and the rear substrate;
electrically connecting a plurality of inter-connection terminals disposed on the rear substrate to each of the thin film solar cells, respectively; and
electrically connecting the inter-connection terminals to each other through a connector.

13. The method of claim 12, wherein
the electrically connecting of the inter-connection terminals to the thin film solar cells further comprises disposing busbars on the thin film solar cells, which penetrate the rear plastic layer and the rear substrate.

14. The method of claim 13, wherein
the thin film solar cells are electrically connected to at least one other thin film solar cell module by an outer connection terminal, which comprises a bypass diode.

15. The method of claim 12, further comprising,
disposing a front plastic layer on the front substrate before arranging the thin film solar cells on the front substrate.

16. The method for manufacturing a thin film solar cell module of claim 15, wherein the rear plastic layer is a polyethylene vinyl acetate sheet.

17. The method for manufacturing a thin film solar cell module of claim 12, wherein the rear plastic layer is a polyethylene vinyl acetate sheet.

18. The method for manufacturing a thin film solar cell module of claim 12, wherein the disposing of the rear plastic layer further comprises disposing a polyethylene vinyl acetate sheet on an entire surface of the thin film solar cells.

19. The thin film solar cell module of claim 1, wherein the inter-connection terminals and connector are configured to bypass one or more thin film solar cells.

20. The thin film solar cell module of claim 20, wherein one or more of the thin film solar cells comprises a fault, and the fault is bypassed.
